(19) United States
(12) Patent Application Publication
(10) Pub. No.: US 2026/0367198 A1
(43) Pub. Date: Nov. 19, 2026

(54) APPARATUS AND METHOD FOR SENSING AN EXTERNAL MAGNETIC FIELD

(71) Applicant: Infineon Technologies AG, Neubiberg (DE)

(72) Inventors: Bernhard ENDRES, Nabburg (DE); Apoorva SHARMA, Unterhaching (DE)

(21) Appl. No.: 19/659,098

(22) Filed: Apr. 27, 2026

(30) Foreign Application Priority Data
May 16, 2025 (DE) 102025119014.3

(51) Int. Cl. G01R 33/09

(52) U.S. Cl. CPC G01R 33/098

(57) ABSTRACT

An apparatus for sensing an external magnetic field includes a sensor bridge including at least one primary magnetoresistive resistor to produce an output signal in response to an external magnetic field. The relationship between the external magnetic field and the output signal is non-linear. The apparatus further includes at least one auxiliary magnetoresistive resistor operatively coupled to the sensor bridge and configured to vary a voltage drop across the sensor bridge as a function of the external magnetic field to at least partially compensate the non-linear relationship between the external magnetic field and the output signal.

### FIELD

### CROSS-REFERENCE TO RELATED APPLICATION

This application claims priority to Germany Patent Application No. 102025119014.3, filed May 16, 2025, the contents of which are incorporated herein by reference in their entireties.

### BACKGROUND

Magnetic field sensors employing vortex-type TMR elements arranged in Wheatstone bridge configurations are known in the art. The term vortex-type refers to a specific magnetization configuration used in certain magnetoresistive sensor elements. In this configuration, the magnetization within a thin, disc-shaped ferromagnetic layer—commonly referred to as “free layer”—forms a closed-loop pattern, curling tangentially around the center of the disc. At the center of the disc, known as the vortex core, the magnetization points out of the plane, either upwards or downwards, creating a stable and well-defined magnetic structure. This vortex state may arise naturally under specific geometric and material conditions, particularly when the disc diameter and thickness are chosen to balance exchange and demagnetizing energies. One of the advantages of the vortex configuration is that it can respond to external magnetic fields in a controlled and continuous manner without undergoing abrupt switching events, which are typical in other magnetization states. This property makes vortex-type TMR elements especially suitable for linear magnetic field sensing applications, where a smooth and predictable sensor response is desired.

These sensors are capable of delivering high sensitivity and are designed to provide a linear response to external magnetic fields over a specified operating range. However, as the range of the sensed magnetic field increases, particularly up to and beyond 100 mT, the linearity of a sensor output signal may tend to degrade. In the context of magnetoresistive sensors arranged in half-bridge or full-bridge configurations, the term sensor output signal refers to a (differential) voltage that develops across specific terminals of the bridge in response to an external magnetic field. This signal arises due to a field-dependent change in resistance of one or more magnetoresistive elements forming part of the bridge. In a half-bridge configuration, one or two active resistive elements may be included, and the output signal may reflect the imbalance between their resistances as they respond to the magnetic field. In a full-bridge configuration, up to four resistive elements may be arranged such that opposing arms of the bridge contain elements with similar field sensitivities, enhancing the differential response. The output signal may be measured as the voltage difference between two nodes of the bridge and may be directly influenced by the variation in resistance caused by the external field. This voltage difference may serve as an electrical representation of the sensed magnetic field and may form a basis for further signal processing. The magnitude and linearity of the output signal depend not only on the sensitivity of the individual elements but also on the specific configuration of the bridge and the uniformity of the resistive response to the applied field.

The degradation of the linearity of sensor output may be attributed to various factors, including material characteristics of the free magnetic layer(s), geometric aspects of the vortex structure, and inherent nonlinearities associated with unbalanced bridge configurations. Additionally, TMR elements may exhibit intrinsic nonlinearity due to a physical relationship between magnetic field and resistance: while conductance may vary linearly with the magnetic field, resistance may follow a reciprocal relationship, leading to curvature in the output signal. These effects can accumulate and become non-neglectable at higher field strengths, resulting in a notable deviation from ideal linear behavior.

An object of the present disclosure may be to improve the linearity of the output signal of magnetoresistive magnetic field sensors, particularly in half-bridge or full-bridge configurations, over extended magnetic field ranges.

### SUMMARY

This object is addressed by apparatuses and methods in accordance with the independent claims. Further embodiments are addressed by the dependent claims.

According to a first aspect, the present disclosure proposes an apparatus for sensing an external magnetic field. The apparatus includes a sensor bridge including at least one primary magnetoresistive resistor. The sensor bridge is configured to produce an output signal in response to an external magnetic field. The relationship between the external magnetic field and the output signal is non-linear. The apparatus further includes an auxiliary magnetoresistive resistor operatively coupled to the sensor bridge and configured to vary a voltage drop across the sensor bridge as a function of the external magnetic field to at least partially compensate the non-linear relationship between the external magnetic field and the output signal.

The proposed apparatus is designed for detecting an external magnetic field. It includes a sensor bridge that incorporates one or more magnetoresistive resistors, which serve as primary sensing elements. When exposed to an external magnetic field, the magnetoresistive resistor changes its resistance, causing the sensor bridge to produce an output signal. However, the relationship between the magnitude of the external magnetic field and the resulting output signal is not strictly linear. This means that the signal deviates from a straight-line response, particularly at higher field strengths, which can limit measurement accuracy. To address this issue, the apparatus further includes an auxiliary magnetoresistive resistor. This auxiliary resistor is electrically connected to the sensor bridge in such a way that it influences the voltage drop across the bridge. Its resistance varies as a function of the external magnetic field, which may cause the voltage across the sensor bridge to change in a controlled manner. By adjusting this voltage drop in response to the field, the auxiliary resistor may contribute to correcting the non-linear behavior of the output signal. In effect, it may introduce a compensatory influence that (at least in part) offsets the inherent non-linearity of the primary sensing element, thereby improving the overall accuracy and linearity of the sensor's response.

In some embodiments, the sensor bridge is connected to a constant external supply selected from the group of a constant supply voltage and a constant supply current. This refers to electrical conditions under which the sensor bridge may operate. In these embodiments, the sensor bridge is not supplied by a varying or adaptive power source but is instead connected to a constant external supply. This supply may be either a constant voltage source or a constant current source.

In some embodiments, the auxiliary magnetoresistive resistor is connected in series with the sensor bridge. This specifies an electrical arrangement of the auxiliary magnetoresistive resistor relative to the sensor bridge. The auxiliary resistor may be positioned in series with the sensor bridge, meaning that the same current flows through both the auxiliary resistor and the bridge. As the resistance of the auxiliary resistor changes with the external magnetic field, it may affect the voltage distribution within the circuit. Specifically, the changing resistance may cause a variation in the voltage drop across the sensor bridge. This variation may be used to influence the output signal of the sensor bridge in a way that can compensate for its inherent non-linear response to the magnetic field. The series configuration may be particularly relevant when the apparatus operates with a constant voltage supply, as it may enable the voltage drop across the sensor bridge to be modulated by the field-dependent behavior of the auxiliary resistor.

In some embodiments, the auxiliary magnetoresistive resistor is connected in parallel with the sensor bridge. This refers to an an alternative configuration in which the auxiliary magnetoresistive resistor may be connected in parallel with the sensor bridge. In this arrangement, the auxiliary resistor may form a separate current path that branches off from the sensor bridge but shares the same voltage terminals. When the apparatus is operated with a constant current supply, changes in the resistance of the auxiliary resistor, which depend on the external magnetic field, may influence how the total current from the supply is distributed between the parallel paths. As the resistance of the auxiliary resistor may decrease with increasing magnetic field, a larger portion of the current may flow through it, and less current may flow through the sensor bridge, and vice versa. This redistribution of current may effectively alter the voltage drop across the sensor bridge as a function of the magnetic field. The resulting voltage modulation may introduce a compensatory effect into the sensor's output signal, which may help reduce or counteract the non-linear response of the sensor bridge to the applied magnetic field.

In some embodiments, the sensor bridge includes a plurality of primary magnetoresistive resistors. The apparatus may include a plurality of auxiliary magnetoresistive resistors, each auxiliary magnetoresistive resistor being connected in parallel with a corresponding one of the primary magnetoresistive resistors. That is, for each primary magnetoresistive resistor in the bridge, there may be a separate auxiliary magnetoresistive resistor electrically connected in parallel with it. That means the auxiliary resistor is connected across the same two nodes as the primary resistor, so both share the same voltage drop. The purpose of this arrangement may be to individually influence the behavior of each bridge leg. Because each auxiliary resistor may exhibit a resistance that varies with the external magnetic field, it can locally modulate the current through its corresponding primary resistor. This local modulation may affect the voltage distribution within the bridge and the overall bridge output signal. By tailoring the field-dependent behavior of each auxiliary resistor, the system may compensate for non-linearities or imbalances in the sensor response on a per-resistor basis, rather than applying a global correction across the whole bridge. This provides a finer level of control, which may lead to improved linearity and symmetry in the sensor's output.

In some embodiments, a variation of the voltage drop across the sensor bridge by the auxiliary magnetoresistive resistor induces a compensatory quadratic component in the output signal that counteracts the non-linear relationship between the external magnetic field and the output signal. This refers to a functional effect that may result from the interaction between the auxiliary magnetoresistive resistor and the sensor bridge. In these embodiments, the auxiliary resistor may vary the voltage drop across the sensor bridge as a function of the external magnetic field. This variation may not be linear but is instead shaped in such a way that it induces a secondary component in the output signal of the sensor bridge. Specifically, the influence of the auxiliary resistor may introduce a quadratic term into the sensor output. This quadratic component may be deliberately configured to have an opposite curvature to the non-linear behavior of the sensor's original response. As a result, it may counteract or compensate for the deviation from linearity that may be observed in the sensor output at higher magnetic field strengths. The overall effect may be a more linear and accurate response across the intended measurement range.

In some embodiments, the apparatus further includes a second auxiliary magnetoresistive resistor operatively coupled to the sensor bridge. The second auxiliary magnetoresistive resistor may be configured to exhibit an inverse field-dependent resistance variation relative to the (first) auxiliary magnetoresistive resistor. This introduces a refinement to the previously described embodiments by including a second auxiliary magnetoresistive resistor. In these embodiments, the apparatus may include not only a first auxiliary resistor but also a second one that is operatively coupled to the sensor bridge. The second auxiliary resistor may be selected or designed such that its resistance changes with the external magnetic field in the opposite manner to that of the first auxiliary resistor. For example, while the resistance of the first auxiliary resistor may increase with increasing magnetic field strength, the resistance of the second auxiliary resistor may decrease under the same conditions, or vice versa. This inverse field-dependent behavior may enable more precise control over the electrical conditions across the sensor bridge. The presence of two auxiliary resistors with opposing field responses may allow for more effective compensation of non-linearities or for stabilization of the overall supply behavior, depending on how the resistors are electrically integrated into the circuit.

In some embodiments, the (first) auxiliary magnetoresistive resistor is connected in parallel with the sensor bridge and the second auxiliary magnetoresistive resistor is connected in series with the sensor bridge. This specifies a particular implementation of the previously described configuration involving two auxiliary magnetoresistive resistors. In these embodiments, the first auxiliary magnetoresistive resistor may be connected in parallel with the sensor bridge, while the second auxiliary magnetoresistive resistor may be connected in series with the sensor bridge. This combination of parallel and series connections may be used to shape the electrical conditions across the bridge more precisely. By placing the first resistor in parallel, the current distribution between the bridge and the auxiliary path may be influenced by changes in the magnetic field. Simultaneously, the series connection of the second resistor may directly affect the voltage drop across the sensor bridge. Because the two resistors are configured to exhibit opposite field-dependent resistance variations, their combined effect may allow for a more stable or tailored compensation of the sensor's non-linear response. This arrangement may provide an additional degree of flexibility in managing the sensor's electrical characteristics as the external magnetic field varies.

In some embodiments, the sensor bridge is configured as a full-bridge or a half-bridge configuration. This relates to possible structural configurations of the sensor bridge. In some embodiments, the sensor bridge may be implemented either as a full-bridge or as a half-bridge. A full-bridge configuration may involve up to four magnetoresistive elements arranged in a Wheatstone bridge, enabling a symmetric and maximized differential signal output. Alternatively, a half-bridge configuration may use only one or two active resistive elements, which may still provide a differential output but with a potentially reduced signal level or sensitivity.

In some embodiments, the auxiliary magnetoresistive resistor is disposed in a dummy region of a common semiconductor die with the primary magnetoresistive resistor. This specifies a physical placement of the auxiliary magnetoresistive resistor relative to the primary sensor structure. In some embodiments, the auxiliary resistor may be located in a dummy region of the same semiconductor die that also contains the primary magnetoresistive resistor(s). The dummy region refers to an area of the die that is not occupied by the active sensing circuitry but is still available for integration of additional components. Placing the auxiliary resistor in such a region may offer practical benefits, such as efficient use of chip area, simplified fabrication, and close thermal or electrical coupling with the primary sensor elements. This proximity may help ensure that both the auxiliary and primary resistors are subject to similar environmental conditions, which can support more consistent and predictable compensation behavior across varying magnetic fields.

In some embodiments, the auxiliary magnetoresistive resistor and the primary magnetoresistive resistor share an identical temperature coefficient of resistance. This relates to the thermal behavior of the resistive elements used in the apparatus. In some embodiments, the auxiliary magnetoresistive resistor and the primary magnetoresistive resistor may be designed or selected such that they exhibit the same temperature coefficient of resistance. The temperature coefficient of resistance characterizes how the resistance of a material changes in response to variations in temperature. If both resistors share the same coefficient, their resistances may change in a similar way when exposed to the same thermal conditions. This similarity may help maintain a stable compensation effect, since temperature-induced resistance changes in the auxiliary resistor may track those in the primary resistor. As a result, the overall balance of the circuit and the intended compensation of non-linearities in the sensor output may remain effective over a range of operating temperatures.

In some embodiments, both the at least one primary magnetoresistive resistor and the auxiliary magnetoresistive resistor are tunnel magnetoresistance (TMR) elements. This defines a specific type of magnetoresistive elements used in the apparatus. In some embodiments, both the primary magnetoresistive resistor, which forms part of the sensor bridge, and the auxiliary magnetoresistive resistor, which is used to influence the voltage drop across the bridge, may be implemented as TMR elements. TMR elements operate based on quantum mechanical tunneling of electrons across an insulating barrier between two ferromagnetic layers, with the resulting resistance depending on the relative orientation of the magnetizations in those layers. By using TMR elements for both the sensing and auxiliary functions, the apparatus may benefit from uniform material properties, similar temperature behavior, and compatible integration processes. This approach may simplify manufacturing and layout while ensuring that the auxiliary resistor behaves in a predictable manner that aligns well with the characteristics of the sensor itself.

According to a further aspect, the present disclosure proposes a method of sensing an external magnetic field. The method includes arranging at least one primary magnetoresistive sensor element in a sensor bridge to produce an output signal in response to an external magnetic field. The relationship between the external magnetic field and the output signal is non-linear. The method further includes connecting at least one auxiliary magnetoresistive resistor to the sensor bridge. The auxiliary magnetoresistive resistor varies a voltage drop across the sensor bridge as a function of the external magnetic field to at least partially compensate the non-linear relationship between the external magnetic field and the output signal.

According to a further aspect, the present disclosure proposes a magnetic field sensor circuit. The magnetic field sensor circuit includes a first terminal connected to a constant external supply, a second terminal connected to a reference potential, and a sensor bridge connected between the first terminal and the second terminal. The sensor bridge has at least one magnetoresistive sensor element to produce an output signal in response to an external magnetic field, wherein a relationship between the external magnetic field and the output signal is non-linear. The magnetic field sensor circuit further includes at least one auxiliary magnetoresistive resistor connected between the first terminal and the second terminal. The auxiliary magnetoresistive resistor is configured to vary a voltage drop across the sensor bridge as a function of the external magnetic field to at least partially compensate the non-linear relationship between the external magnetic field and the output signal.

This describes a magnetic field sensor circuit that is electrically connected between two defined terminals. The first terminal is coupled to a constant external supply, which may provide a fixed voltage or a fixed current to power the circuit. This supply serves as the source of electrical energy required for the operation of the sensor bridge and the auxiliary components. The second terminal is connected to a reference potential, which may correspond to ground. This reference establishes a stable electrical baseline against which the voltages within the circuit can be measured and regulated. The sensor bridge is arranged between these two terminals, meaning that it spans the supply and ground connections. As a result, the electrical potential applied across the bridge is determined by the constant supply at the first terminal and the reference level at the second terminal. The auxiliary magnetoresistive resistor is also connected between these same two terminals, either in parallel or in series with the sensor bridge. In a parallel configuration, the auxiliary resistor shares the same voltage drop as the bridge and may influence the current distribution between the two paths. In a series configuration, the resistor directly affects the voltage seen by the bridge. In both cases, the auxiliary resistor varies the voltage drop across the sensor bridge as a function of the external magnetic field. This variation may introduce a compensatory effect into the sensor's output signal, which may serve to correct or reduce the non-linear response of the sensor to the applied magnetic field. The defined connection between a constant supply and a reference potential provides a controlled electrical framework in which such compensation mechanisms can operate effectively.

Thus, embodiments relate to a magnetic field sensing concept that may improve the linearity of the sensor output by incorporating an auxiliary magnetoresistive resistor. This auxiliary resistor is configured to vary the voltage drop across a sensor bridge as a function of the external magnetic field. By modulating the electrical conditions of the sensor bridge in this way, the auxiliary resistor may introduce a compensatory effect that counteracts the inherent non-linearity of the sensor's response. Embodiments may be implemented with minimal modifications to existing sensor designs and may enable accurate magnetic field measurements over an extended range without sacrificing sensitivity or requiring complex material changes.

### BRIEF DESCRIPTION OF THE DRAWINGS

Some examples of apparatuses and/or methods will be described in the following by way of example only, and with reference to the accompanying figures, in which

FIG. 1 illustrates an example of a linear output response of a vortex-based TMR sensor as a function of an applied external magnetic field;

FIG. 2A illustrates an apparatus for sensing an external magnetic field according to an embodiment of the present disclosure;

FIG. 2B illustrates a conceptual representation of a functional behavior of the apparatus shown in FIG. 2A;

FIG. 2C shows an arrangement, wherein an individual auxiliary magnetoresistive resistor may be coupled in parallel to a corresponding primary magnetoresistive resistor R1 to R4 within a sensor bridge;

FIG. 3A illustrates an apparatus for sensing an external magnetic field according to another embodiment of the present disclosure; and

FIG. 3B illustrates an apparatus for sensing an external magnetic field according to a further embodiment of the present disclosure.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

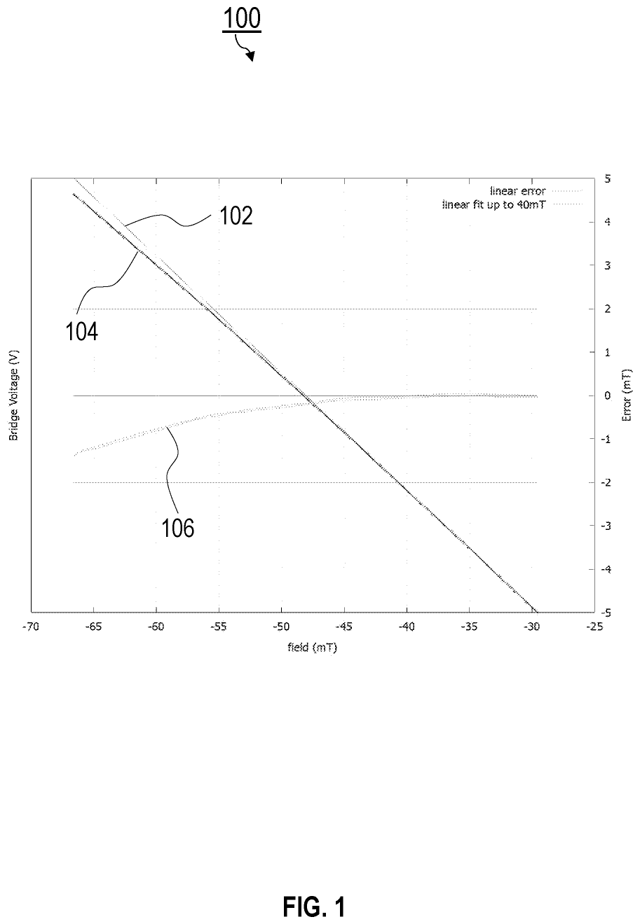

A diagram 100 shown in FIG. 1 illustrates an example of a linear output response of a vortex-based TMR sensor as a function of an applied external magnetic field. A sensor output signal may be represented in terms of bridge voltage, plotted against an external magnetic field strength. FIG. 1 provides a visual representation of a deviation between a measured sensor response 104 and an idealized linear response 102, highlighting the non-linearity problem addressed by the present disclosure.

The curve labeled 102 represents a linear fit of the sensor output signal within a limited field range up to approximately 40 mT. This line reflects the expected response of the sensor under ideal conditions where the output voltage would vary proportionally with the magnetic field. As shown, this reference line 102 extends linearly beyond the initial fit range to illustrate how the actual sensor signal deviates as the field increases.

The curve labeled 104 corresponds to the actual sensor output signal as measured over a broader field range. As evident from FIG. 1, this curve 104 begins to flatten as the magnetic field increases, bending downward relative to the linear fit 102. This behavior is indicative of a systematic curvature in the sensor response, particularly at higher field strengths. The flattening of the sensor output may be caused by magnetic saturation effects in the vortex free layer or by other field-dependent magnetic or electrical properties of the TMR elements.

A curve labeled 106 shows the error, which quantifies the deviation between the actual sensor output and the ideal linear response. This error 106 is expressed in terms of equivalent magnetic field deviation and serves to illustrate the magnitude of the non-linearity. The shape of curve 106 demonstrates that the error increases with the applied field and follows a parabolic trend, suggesting the presence of a quadratic component in the output deviation.

The behavior illustrated in FIG. 1 confirms that curvature in the sensor output signal may be a dominant contributor to non-linearity in the output response of vortex-based TMR sensors. This curvature becomes increasingly non-neglectable in extended field ranges, such as from 0 to 100 mT. The observed non-linearity may lead to errors of up to 10% in some cases and may significantly limit the applicability of the sensor in high-accuracy magnetic field sensing applications.

To address this issue, the present disclosure proposes a solution in which a voltage drop across a sensor bridge may be varied as a function of the external magnetic field. This may be achieved by coupling at least one auxiliary magnetoresistive resistor to the sensor bridge in a configuration that modulates the voltage drop across the sensor bridge. By introducing a field-dependent modulation that may generate a compensatory quadratic component in the output signal, the curvature in the sensor response may be at least partially corrected. This technique may enable improved linearity without requiring changes to the underlying sensor geometry or material system, offering a practical and effective enhancement for next-generation magnetic field sensors.

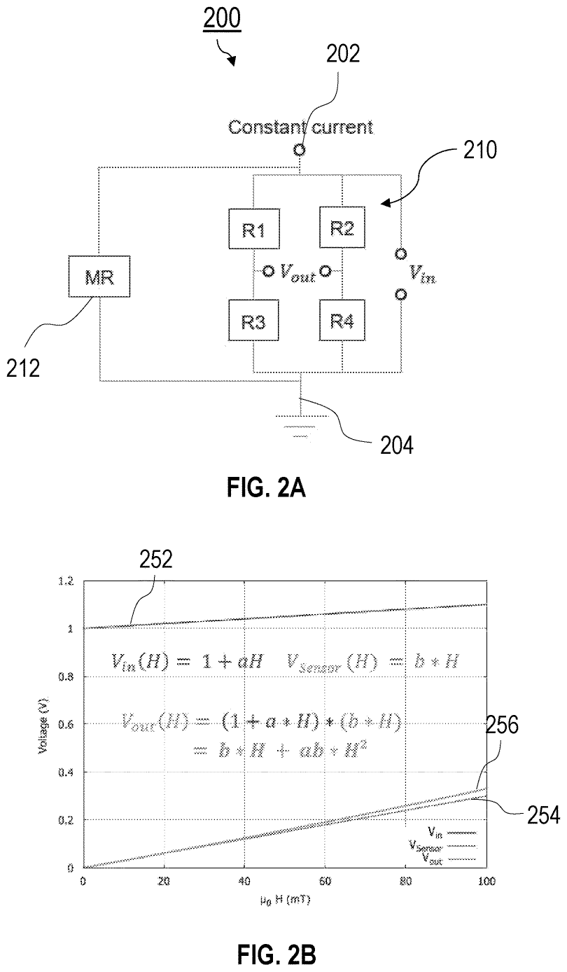

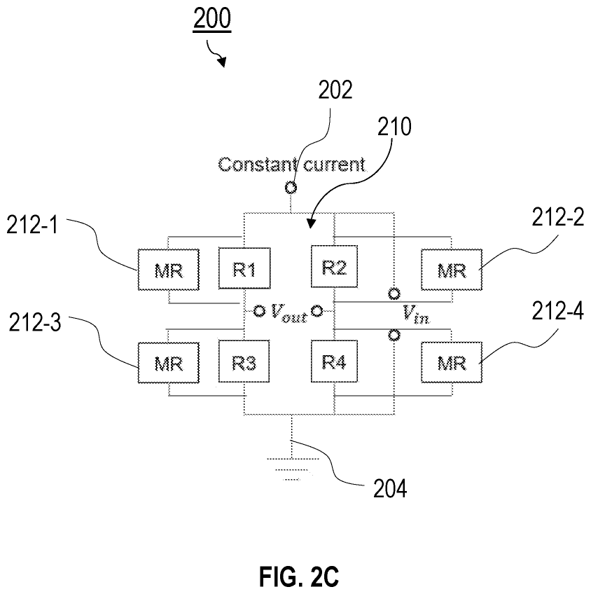

FIG. 2A illustrates an apparatus 200 for sensing an external magnetic field according to an embodiment of the present disclosure. The apparatus 200 includes a first terminal 202 configured to receive a constant external supply, which in this embodiment may be a constant current source. A second terminal 204 is provided to establish a reference potential, which may correspond to an electrical ground. These terminals define electrical input conditions for the sensor circuitry.

The apparatus 200 further comprises a sensor bridge 210 coupled between the first terminal 202 and the second terminal 204. Sensor bridge 210 includes at least one primary magnetoresistive resistor. In the illustrated example, the sensor bridge 210 is configured as a Wheatstone bridge and comprises four resistive elements labeled R1, R2, R3, and R4. These resistive elements may each comprise a magnetoresistive element whose resistance varies in response to an external magnetic field. The sensor bridge 210 is arranged between the first terminal 202 and the second terminal 204 such that an input voltage Vin is established across the sensor bridge 210 in operation. A sensor output voltage Vout is taken from intermediate nodes of the bridge 210 and may vary as a function of the external magnetic field due to the field-dependent resistance changes of the magnetoresistive elements.

To compensate for non-linearities in the output signal Vout of the sensor bridge 210, the apparatus 200 additionally comprises an auxiliary magnetoresistive resistor 212. This auxiliary magnetoresistive resistor 212 is operatively coupled to the sensor bridge 210 and, in this embodiment, is connected in parallel with it. That is, the auxiliary resistor 212 is electrically connected between the same first terminal 202 and second terminal 204 as the sensor bridge 210. As the external magnetic field varies, the resistance of the auxiliary magnetoresistive resistor 212 also varies in a field-dependent manner. Since the apparatus 200 is operated under constant current conditions, a change in the resistance of the auxiliary magnetoresistive resistor 212 causes a redistribution of the total supply current between the parallel branches formed by the sensor bridge 210 and the auxiliary resistor 212.

This redistribution of current modifies the voltage drop across Vin the sensor bridge 210 as a function of the magnetic field. Specifically, as the resistance of the auxiliary magnetoresistive resistor 212 decreases with increasing field, more current flows through that path, resulting in a lower voltage across the sensor bridge 210, and vice versa. This field-dependent voltage modulation introduces a compensatory effect in the sensor output Vout, which may reduce the non-linearity caused by the intrinsic characteristics of the magnetoresistive elements in the bridge. Thus, the configuration shown in FIG. 2A may enable a simple and effective technique for enhancing the linearity of magnetoresistive magnetic field sensors, particularly under constant current operating conditions.

FIG. 2B illustrates a conceptual representation of the functional behavior of the apparatus 200 shown in FIG. 2A. The graph in FIG. 2B plots voltage as a function of the external magnetic field strength, labeled μ0H, and shows how various voltage components vary with the field. FIG. 2B may be used to explain how the combination of the sensor bridge 210 and the auxiliary magnetoresistive resistor 212 affects the overall output signal of the apparatus.

In this context, the curve 252 labeled Vin(H) represents the voltage across the sensor bridge 210, which may be modulated by the field-dependent resistance of the auxiliary resistor 212. Under constant current operation, as shown in FIG. 2A, the total current provided at terminal 202 remains fixed. However, the current is distributed between the parallel paths of the bridge 210 and the auxiliary magnetoresistive resistor 212, depending on their respective resistances. As the resistance of the auxiliary magnetoresistive resistor 212 changes with the magnetic field H, it alters the voltage drop across the sensor bridge 210. In this simplified model, this modulation is expressed as Vin(H)=1+aH, where a is a proportionality constant.

The curve 254 in FIG. 2B represents the intrinsic response of the sensor bridge 210, assuming an idealized linear relationship between the output and the magnetic field, expressed as VSensor(H)=bH, where b is the sensitivity of the bridge.

The combined effect of the modulated input voltage and the sensor response is shown by curve 256 labeled Vout(H). This output voltage results from the product of the modulated bridge input voltage and the intrinsic sensor response:

Vout(H)=Vin(H)·VSensor(H)=(1+aH)(bH)=bH+abH2

This expression indicates that the output voltage may include both a linear component bH and a quadratic component abH2, which reflects a curvature in the output characteristic.

In practice, such a quadratic term may already be present in the intrinsic response of the sensor due to material and structural factors, as illustrated in FIG. 1. The auxiliary magnetoresistive resistor 212 may be deliberately selected and configured to introduce a field-dependent modulation of the input voltage Vin(H) in such a way that a resulting quadratic term counteracts or compensates the intrinsic curvature of the sensor output Vout(H). In other words, rather than causing the quadratic term, the auxiliary resistor 212 may be used to generate an opposing quadratic component that reduces a net non-linearity of the sensor output.

The magnetoresistive elements in the sensor bridge 210 exhibit a small but systematic curvature in their field-to-voltage transfer characteristic, so the bridge 210 on its own delivers an output that already contains an unwanted quadratic contribution. When the auxiliary magnetoresistive resistor 212 is connected in parallel under constant-current supply conditions, any change in its resistance with the external field redistributes the fixed total current between the auxiliary path and the bridge. If the auxiliary resistance falls as the field rises, more current is diverted through the auxiliary path, leaving less current for the bridge 210 and therefore reducing the voltage across it; if the auxiliary resistance rises with field, the opposite effect occurs. In either case the voltage that actually biases the bridge 210 no longer remains constant but changes essentially linearly with the magnetic field. Because the bridge output is proportional to the product of this field-dependent bias voltage and the bridge's own field-dependent resistance change, the linear modulation of the bias voltage is multiplied by the bridge's approximately linear sensitivity, so a secondary quadratic term appears in the overall output signal. By selecting the sign and magnitude of the auxiliary resistor's field dependence so that this secondary quadratic term bends in the opposite direction to the intrinsic curvature of the bridge, the two contributions superimpose and partially cancel. The net result may be a noticeable reduction in the remaining curvature and therefore a considerably more linear sensor output over the intended field range.

To support the proposed concept, simulation results were obtained to evaluate the effect of the auxiliary magnetoresistive resistor 212 on the linearity of the sensor output. These simulations qualitatively confirm that the inclusion of such a resistor may lead to a reduction in the non-linearity of the sensor signal. In particular, the simulations show that, in the absence of the auxiliary resistor, the output signal deviates noticeably from a linear trend as the magnetic field increases. This deviation becomes more pronounced in the higher field range, resulting in a curvature that limits the accuracy of the sensor.

When the auxiliary magnetoresistive resistor 212 is introduced and appropriately coupled to the sensor bridge 210, the overall response of the sensor becomes substantially more linear. The simulations indicate that the deviation from an ideal linear output may be reduced by approximately a factor of four. This improved linearity results from the deliberate modulation of the electrical conditions across the sensor bridge 210, which compensates for the inherent curvature in the sensor's response.

In the embodiment shown in FIG. 2A, the auxiliary magnetoresistive resistor 212 is connected in parallel with the entire sensor bridge 210 to achieve a global modulation of the bridge supply voltage under constant current operation. However, in an alternative embodiment shown in FIG. 2C, instead of using a single auxiliary resistor, a plurality of auxiliary magnetoresistive resistors 212-1 to 212-4 may be employed. In this arrangement, each individual auxiliary magnetoresistive resistor may be coupled in parallel to a corresponding primary magnetoresistive resistor R1 to R4 within the sensor bridge 210. Each auxiliary resistor may be selected or configured to exhibit a specific field-dependent resistance characteristic tailored to the behavior of its associated primary resistor. This may allow for localized compensation of curvature at each bridge arm rather than a global voltage modulation across the entire bridge. By adjusting the properties of each auxiliary resistor individually, the resulting voltage drops across the bridge arms may be more finely tuned as a function of the magnetic field. This may enhance the overall symmetry of the bridge and allow more precise cancellation of the quadratic error components associated with the intrinsic non-linearity of the individual magnetoresistive elements. Such an approach may offer an additional degree of flexibility.

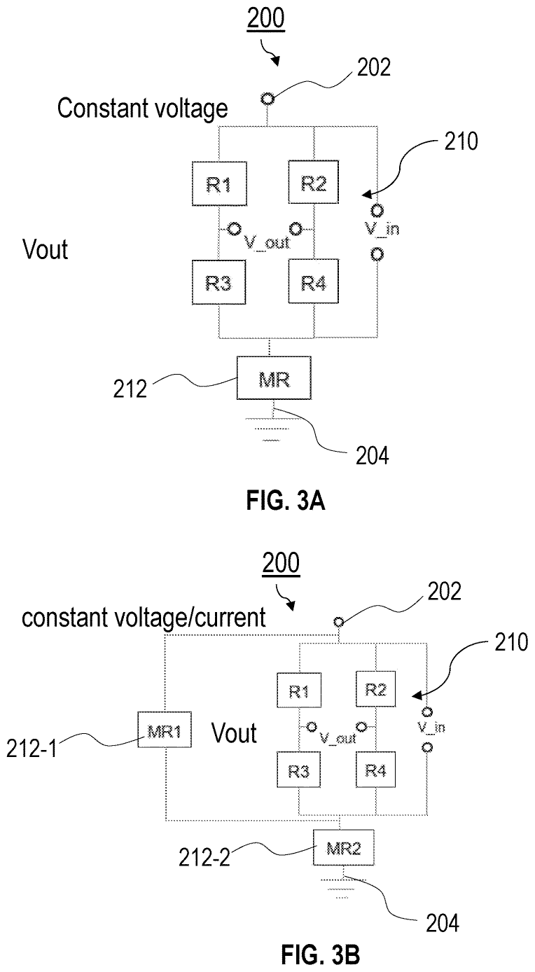

FIG. 3A illustrates an apparatus 200 for sensing an external magnetic field according to another embodiment of the present disclosure. Similar to the embodiment shown in FIG. 2A, the apparatus 200 shown in FIG. 3A includes a first terminal 202 configured to receive a constant external supply, and a second terminal 204 that provides a reference potential, such as ground. These terminals define the electrical boundary conditions for the operation of the sensor circuit.

The apparatus 200 comprises a sensor bridge 210 that includes at least one primary magnetoresistive resistor. In the configuration shown, the sensor bridge 210 is implemented as a Wheatstone bridge and includes four resistive elements labeled R1, R2, R3, and R4. These elements may comprise magnetoresistive materials whose resistance varies in response to the external magnetic field. The bridge 210 is positioned between the first terminal 202 and the second terminal 204 such that an input voltage Vin is applied across the bridge 210, and an output voltage Vout may be derived from the center nodes between the resistors R1, R3 and R2, R4.

In this embodiment, the apparatus 200 further includes an auxiliary magnetoresistive resistor 212 that is connected in series with the sensor bridge 210. Specifically, the auxiliary resistor 212 is positioned between the lower end of the sensor bridge 210 and the second terminal 204, such that all current flowing through the bridge 210 also passes through the auxiliary resistor 212. As the resistance of the auxiliary resistor 212 varies with the external magnetic field, the voltage drop across the sensor bridge 210 is modulated accordingly.

While FIG. 3A shows the auxiliary magnetoresistive resistor 212 connected between the lower end of the sensor bridge 210 and the second terminal 204, the same compensation principle can be achieved by positioning the auxiliary resistor at the opposite side of the bridge. In this alternative arrangement, the auxiliary resistor 212 is inserted between the upper end of the sensor bridge 210 and the first terminal 202. Because the bridge current must still traverse the auxiliary resistor 212, any field-dependent change in the resistance of the auxiliary resistor 212 modulates the voltage Vin that is actually applied across the bridge 212.

When operated with a constant voltage source connected at terminal 202, the field-dependent resistance of the auxiliary resistor 212 causes a change in the voltage Vin that appears across the sensor bridge 210. This modulation of the bridge voltage as a function of the magnetic field alters the electrical conditions under which the sensor bridge 210 operates. Because the sensor output Vout is proportional to both the internal resistance differences and the voltage supplied across the bridge, this configuration introduces a field-dependent scaling effect into the sensor output.

The result is that a compensatory quadratic component may be introduced into the output signal Vout, which can counteract the curvature caused by the inherent non-linearity of the magnetoresistive elements. By adjusting the characteristics of the auxiliary resistor 212 and its interaction with the sensor bridge 210, the overall linearity of the sensor response may be improved. The configuration shown in FIG. 3A is particularly suited for systems operating with a constant voltage supply and provides a straightforward means for enhancing sensor performance without significant changes to the base sensor design.

Simulation results obtained for the constant voltage operating mode qualitatively confirm the effectiveness of the proposed compensation approach based on an auxiliary magnetoresistive resistor. In a configuration without the auxiliary resistor, the sensor output exhibits a noticeable deviation from a linear relationship with respect to the applied magnetic field. This deviation, which manifests as curvature in the output signal, increases with the field magnitude and results in a measurable non-linearity.

When the auxiliary resistor 212 is included and connected in series with the sensor bridge 210, the simulations show a distinct improvement in the linearity of the output signal. Although the output still exhibits some degree of curvature, the overall deviation from an ideal linear response may be reduced. This behavior supports the conclusion that the auxiliary resistor 212 modulates the voltage drop across the sensor bridge in a manner that introduces a compensatory effect into the sensor signal. As a result, the non-linear characteristics of the sensor response are at least partially counteracted, leading to enhanced accuracy in the measurement of magnetic fields under constant voltage conditions. These findings reinforce the versatility of the proposed concept and demonstrate its applicability across different supply configurations.

FIG. 3B illustrates an apparatus 200 for sensing an external magnetic field according to a further embodiment of the present disclosure. The apparatus 200 includes a first terminal 202 for receiving a constant external supply, which may be configured as a constant voltage or constant current source, and a second terminal 204 that provides a reference potential, such as electrical ground. These terminals define the supply path for powering the sensor circuitry.

The apparatus 200 further comprises a sensor bridge 210, implemented in the form of a Wheatstone bridge and including at least one primary magnetoresistive resistor. In the illustrated configuration, the bridge 210 comprises four magnetoresistive elements R1, R2, R3, and R4. These resistors are arranged in a standard bridge topology, where the voltage drop between the upper and lower terminals defines the input voltage Vin, and the differential output Vout is taken from the midpoints between the left and right branches of the bridge 210. The resistance of the primary magnetoresistive elements may vary as a function of the external magnetic field, producing a corresponding change in the output signal.

In this embodiment, the apparatus 200 includes two auxiliary magnetoresistive resistors, labeled MR1 (212-1) and MR2 (212-2), which are connected to the sensor bridge 210 in parallel and series configurations, respectively. The auxiliary resistor MR1 (212-1) is connected in parallel with the sensor bridge 210 between the first terminal 202 and the second terminal 204. In contrast, the second auxiliary resistor MR2 (212-2) is connected in series between the sensor bridge 210 and the second terminal 204.

The combination of the two auxiliary resistors 212-1, 212-2 may provide an enhanced level of control over the voltage drop Vin across the sensor bridge 210. Each auxiliary resistor may exhibit a field-dependent resistance characteristic, and in some implementations, they may be configured to respond in opposite directions to changes in the magnetic field. For example, MR1 may increase its resistance with field strength, while MR2 decreases, or vice versa. This complementary behavior allows the voltage drop across the sensor bridge 210 to be modulated while minimizing the change of the total resistance of the apparatus 200. This may keep the supply voltage or supply current stable over a large field range.

The implementation of auxiliary magnetoresistive resistors that respond in opposite directions to changes in the magnetic field can be achieved via the orientation of the reference system as used in the bridge elements.

The inclusion of both MR1 and MR2 may enable dynamic adjustment of the sensor bridge bias, resulting in an improved linearity of the output signal Vout. This configuration may support compensation of curvature effects that arise due to the intrinsic non-linearity of the magnetoresistive elements, magnetic material properties, or bridge asymmetry. The embodiment shown in FIG. 3B may thereby provide an extended compensation mechanism for enhanced accuracy and robustness in magnetic field sensing applications.

For example, semiconductor die may contain four primary magnetoresistive resistors (R1-R4) arranged as a Wheatstone bridge in an active region, where they may provide a core magnetic-field-sensing function. Non-active thin-film magnetoresistive (TMR) cells—e.g., included at the periphery of the primary magnetoresistive resistors (R1-R4) for process homogenization—may, in principle, be electrically repurposed as auxiliary sensing elements without consuming extra silicon area. That is, the auxiliary magnetoresistive resistor 212 may be disposed in a dummy region of a common semiconductor die with the primary magnetoresistive resistor(s). Integrating these elements in the same chip—and within the same TMR layer stack—may keep the overall footprint compact while maintaining full sensor functionality.

The co-location of the auxiliary magnetoresistive resistor and the primary sensing resistors R1 through R4 on the same die may provide several advantages. These may include improved thermal coupling, simplified routing of interconnects, and uniformity in material properties and fabrication tolerances. Furthermore, integration on a common die may facilitate temperature tracking, as the auxiliary and primary resistors are likely to experience similar environmental conditions. This arrangement may support improved compensation of non-linearities in the sensor output, as described in the context of earlier embodiments, without introducing significant complexity to the fabrication or layout process.

In summary, the present disclosure provides an efficient and easily integrable approach to improving the linearity of magnetoresistive sensor systems, in particular vortex-based TMR sensors. By making use of an auxiliary resistor whose resistance varies in a controlled manner with the external magnetic field, the current or voltage applied across the sensor bridge can be modulated to generate a compensatory quadratic component. This component may be deliberately tuned to counteract the inherent non-linearities typically observed in the sensor output, especially at higher magnetic field strengths.

The proposed solution may be implemented without the need for new materials or manufacturing processes. For example, a vortex-based TMR resistor identical to the primary sensing elements may be used as the auxiliary resistor, thereby maintaining compatibility with existing fabrication flows. The auxiliary resistor may be connected in parallel or in series with the sensor bridge, depending on whether the sensor operates under constant current or constant voltage conditions. In some embodiments, a plurality of auxiliary resistors may be connected locally to individual bridge resistors, offering a more granular compensation scheme.

Overall, the proposed solution may enhance the functional linearity of a sensor system while preserving sensitivity, facilitating accurate magnetic field measurements across an extended range, and offering a compact and robust solution suitable for integration in next-generation sensing applications.

The aspects and features described in relation to a particular one of the previous examples may also be combined with one or more of the further examples to replace an identical or similar feature of that further example or to additionally introduce the features into the further example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps,-functions,-processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### ASPECTS

The following provides an overview of some Aspects of the present disclosure:

Aspect 1: An apparatus for sensing an external magnetic field, comprising: a sensor bridge comprising at least one primary magnetoresistive resistor to produce an output signal in response to an external magnetic field, wherein the external magnetic field and the output signal have non-linear relationship; and at least one auxiliary magnetoresistive resistor operatively coupled to the sensor bridge and configured to vary a voltage drop across the sensor bridge as a function of the external magnetic field to at least partially compensate the non-linear relationship between the external magnetic field and the output signal.

Aspect 2: The apparatus of Aspect 1, wherein the sensor bridge is connected to a constant external supply selected from the group of a constant supply voltage and a constant supply current.

Aspect 3: The apparatus of any of Aspects 1-2, wherein the auxiliary magnetoresistive resistor is connected in series with the sensor bridge.

Aspect 4: The apparatus of any of Aspects 1-3, wherein the auxiliary magnetoresistive resistor is connected in parallel with the sensor bridge.

Aspect 5: The apparatus of any of Aspects 1-4, wherein the sensor bridge comprises a plurality of primary magnetoresistive resistors, and wherein the apparatus comprises a plurality of auxiliary magnetoresistive resistors, each auxiliary magnetoresistive resistor being connected in parallel with a corresponding one of the primary magnetoresistive resistors.

Aspect 6: The apparatus of any of Aspects 1-5, wherein a variation of the voltage drop across the sensor bridge by the auxiliary magnetoresistive resistor induces a compensatory quadratic component in the output signal that counteracts the non-linear relationship.

Aspect 7: The apparatus of any of Aspects 1-6, further comprising: a second auxiliary magnetoresistive resistor operatively coupled to the sensor bridge, the second auxiliary magnetoresistive resistor being configured to exhibit an inverse field-dependent resistance variation relative to the auxiliary magnetoresistive resistor.

Aspect 8: The apparatus of Aspect 7, wherein the auxiliary magnetoresistive resistor is connected in parallel with the sensor bridge and the second auxiliary magnetoresistive resistor is connected in series with the sensor bridge.

Aspect 9: The apparatus of any of Aspects 1-8, wherein the sensor bridge is configured as a full-bridge configuration or a half-bridge configuration.

Aspect 10: The apparatus of any of Aspects 1-9, wherein the auxiliary magnetoresistive resistor is disposed in a dummy region of a common semiconductor die with the primary magnetoresistive resistor.

Aspect 11: The apparatus of any of Aspects 1-10, wherein the auxiliary magnetoresistive resistor and the primary magnetoresistive resistor share an identical temperature coefficient of resistance.

Aspect 12: The apparatus of any of Aspects 1-11, wherein both the at least one primary magnetoresistive resistor and the auxiliary magnetoresistive resistor are tunnel magnetoresistance elements.

Aspect 13: A method of sensing an external magnetic field, comprising: arranging at least one primary magnetoresistive sensor element in a sensor bridge to produce an output signal in response to an external magnetic field, wherein the external magnetic field and the output signal have a non-linear relationship; and connecting at least one auxiliary magnetoresistive resistor to the sensor bridge, the auxiliary magnetoresistive resistor varying a voltage drop across the sensor bridge as a function of the external magnetic field to at least partially compensate the non-linear relationship between the external magnetic field and the output signal.

Aspect 14: A magnetic field sensor circuit, comprising: a first terminal connected to a constant external supply; a second terminal connected to a reference potential; a sensor bridge connected between the first terminal and the second terminal, the sensor bridge having at least one magnetoresistive sensor element to pro-duce an output signal in response to an external magnetic field, wherein the external magnetic field and the output signal have non-linear relationship; and at least one auxiliary magnetoresistive resistor connected between the first terminal and the second terminal, the auxiliary magnetoresistive resistor being configured to vary a voltage drop across the sensor bridge as a function of the external magnetic field to at least partially compensate the non-linear relationship between the external magnetic field and the output signal.

Aspect 15: The magnetic field sensor circuit according to Aspect 14, wherein the auxiliary magnetoresistive resistor is connected in parallel with the sensor bridge between the first terminal and the second terminal.

Aspect 16: The magnetic field sensor circuit according to Aspect 15, wherein a second auxiliary magnetoresistive resistor is connected in series with the sensor bridge.

Aspect 17: The magnetic field sensor circuit according to any of Aspects 14-16, wherein the auxiliary magnetoresistive resistor is connected in series with the sensor bridge.

Aspect 18: A system configured to perform one or more operations recited in one or more of Aspects 1-17.

Aspect 19: An apparatus comprising means for performing one or more operations recited in one or more of Aspects 1-17.

1. An apparatus for sensing an external magnetic field, comprising:
a sensor bridge comprising at least one primary magnetoresistive resistor to produce an output signal in response to an external magnetic field, wherein the external magnetic field and the output signal have non-linear relationship; and
at least one auxiliary magnetoresistive resistor operatively coupled to the sensor bridge and configured to vary a voltage drop across the sensor bridge as a function of the external magnetic field to at least partially compensate the non-linear relationship between the external magnetic field and the output signal.

2. The apparatus of claim 1, wherein the sensor bridge is connected to a constant external supply selected from the group of a constant supply voltage and a constant supply current.

3. The apparatus of claim 1, wherein the auxiliary magnetoresistive resistor is connected in series with the sensor bridge.

4. The apparatus of claim 1, wherein the auxiliary magnetoresistive resistor is connected in parallel with the sensor bridge

5. The apparatus of claim 1, wherein the sensor bridge comprises a plurality of primary magnetoresistive resistors, and
wherein the apparatus comprises a plurality of auxiliary magnetoresistive resistors, each auxiliary magnetoresistive resistor being connected in parallel with a corresponding one of the primary magnetoresistive resistors.

6. The apparatus of claim 1, wherein a variation of the voltage drop across the sensor bridge by the auxiliary magnetoresistive resistor induces a compensatory quadratic component in the output signal that counteracts the non-linear relationship.

7. The apparatus of claim 1, further comprising:
a second auxiliary magnetoresistive resistor operatively coupled to the sensor bridge the second auxiliary magnetoresistive resistor being configured to exhibit an inverse field-dependent resistance variation relative to the auxiliary magnetoresistive resistor

8. The apparatus of claim 7, wherein the auxiliary magnetoresistive resistor is connected in parallel with the sensor bridge and the second auxiliary magnetoresistive resistor is connected in series with the sensor bridge.

9. The apparatus of claim 1, wherein the sensor bridge is configured as a full-bridge configuration or a half-bridge configuration.

10. The apparatus of claim 1, wherein the auxiliary magnetoresistive resistor is disposed in a dummy region of a common semiconductor die with the primary magnetoresistive resistor.

11. The apparatus of claim 1, wherein the auxiliary magnetoresistive resistor and the primary magnetoresistive resistor share an identical temperature coefficient of resistance.

12. The apparatus of claim 1, wherein both the at least one primary magnetoresistive resistor and the auxiliary magnetoresistive resistor are tunnel magnetoresistance elements.

13. A method of sensing an external magnetic field, comprising:
arranging at least one primary magnetoresistive sensor element in a sensor bridge to produce an output signal in response to an external magnetic field, wherein the external magnetic field and the output signal have a non-linear relationship; and
connecting at least one auxiliary magnetoresistive resistor to the sensor bridge the auxiliary magnetoresistive resistor varying a voltage drop across the sensor bridge as a function of the external magnetic field to at least partially compensate the non-linear relationship between the external magnetic field and the output signal.

14. A magnetic field sensor circuit, comprising:
a first terminal connected to a constant external supply;
a second terminal connected to a reference potential;
a sensor bridge connected between the first terminal and the second terminal, the sensor bridge having at least one magnetoresistive sensor element to pro-duce an output signal in response to an external magnetic field, wherein the external magnetic field and the output signal have non-linear relationship; and
at least one auxiliary magnetoresistive resistor connected between the first terminal and the second terminal, the auxiliary magnetoresistive resistor being configured to vary a voltage drop across the sensor bridge as a function of the external magnetic field to at least partially compensate the non-linear relationship between the external magnetic field and the output signal.

15. The magnetic field sensor circuit according to claim 14, wherein the auxiliary magnetoresistive resistor is connected in parallel with the sensor bridge between the first terminal and the second terminal.

16. The magnetic field sensor circuit according to claim 15, wherein a second auxiliary magnetoresistive resistor is connected in series with the sensor bridge.

17. The magnetic field sensor circuit according to claim 14, wherein the auxiliary magnetoresistive resistor is connected in series with the sensor bridge.
